(19) United States
(12) Patent Application Publication
(10) Pub. No.: US 2025/0210330 A1
(43) Pub. Date: Jun. 26, 2025

(54) PLASMA PROCESSING APPARATUS AND SUBSTRATE PROCESSING SYSTEM

(71) Applicant: Tokyo Electron Limited, Tokyo (JP)

(72) Inventors: Naoki MATSUMOTO, Miyagi (JP); Satoru NAKAMURA, Miyagi (JP); Manabu ISHIKAWA, Miyagi (JP); Hiroki SATO, Miyagi (JP); Takumi IMAHASHI, Miyagi (JP); Yuki KUMAGAI, Miyagi (JP); Sho OIKAWA, Miyagi (JP); Ryo KURODA, Tokyo (JP)

(73) Assignee: Tokyo Electron Limited, Tokyo (JP)

(21) Appl. No.: 19/074,745

(22) Filed: Mar. 10, 2025

Related U.S. Application Data
(63) Continuation of application No. PCT/JP2024/028533, filed on Aug. 8, 2024.

(30) Foreign Application Priority Data
Sep. 29, 2023 (JP) 2023-169430
Apr. 26, 2024 (JP) 2024-072408

(51) Int. Cl. H01J 37/32

(52) U.S. Cl. CPC H01J 37/32807; H01J 37/32642; H01J 37/32697; H01J 37/32715; H01J 37/32889; H01J 37/3299; H01J 2237/334

(57) ABSTRACT

A plasma processing apparatus includes a chamber, a substrate support, an edge ring, a lifter, a plasma generator, and a bias power supply. The substrate support is in the chamber. The lifter raises and lowers the edge ring relative to the substrate support. The substrate support includes a base electrically coupled to at least one of the bias power supply or a radio-frequency power supply in a plasma generator, and an electrostatic chuck on the base. The lifter includes a conductive ring and a connector. The conductive ring is electrically coupled to the edge ring while supporting the edge ring placed on the conductive ring. The connector maintains electrical coupling between the conductive ring and the base for movement of the edge ring and the conductive ring with the lifter.

### CROSS-REFERENCE TO RELATED APPLICATIONS

This application is a bypass continuation application of International Application No. PCT/JP2024/028533 having an international filing date of Aug. 8, 2024 and designating the United States, the international application being based upon and claiming the benefit of priority from Japanese Patent Application Nos. 2023-169430 and 2024-072408, filed on Sep. 29, 2023, and Apr. 26, 2024, respectively, the entire contents of each are incorporated herein by reference.

### TECHNICAL FIELD

Exemplary embodiments of the disclosure relate to a plasma processing apparatus and a substrate processing system.

### BACKGROUND

A plasma processing apparatus is used to perform plasma processing on a substrate. The plasma processing apparatus includes a chamber and a substrate support. The substrate support is in the chamber. The substrate support includes a base and an electrostatic chuck. The base is coupled to a bias power supply that generates an electrical bias to draw ions from plasma into the substrate. The electrostatic chuck supports the substrate and an edge ring to surround the substrate. Patent Literature 1 describes a plasma processing apparatus that raises and lowers the edge ring.

### PRIOR ART DOCUMENT

### Patent Document

Patent Document 1: Japanese patent laid-open publication No. 2020-113753

### SUMMARY

A plasma processing apparatus according to one exemplary embodiment includes a chamber, a substrate support, an edge ring, a lifter, a plasma generator, and a bias power supply. The substrate support is in the chamber. The edge ring is conductive and surrounds a substrate on the substrate support. The lifter raises and lowers the edge ring. The plasma generator includes a radio-frequency power supply. The plasma generator generates plasma in the chamber. The bias power supply generates an electrical bias to draw ions from the plasma into the substrate on the substrate support. The substrate support includes a base electrically coupled to at least one of the bias power supply or the radio-frequency power supply, and an electrostatic chuck on the base. The lifter includes a conductive ring, a rod, an actuator, and a connector. The conductive ring is electrically coupled to the edge ring while supporting the edge ring placed on the conductive ring. The rod extends in a vertical direction below the conductive ring. The actuator raises and lowers the edge ring with the rod and the conductive ring. The connector electrically couples the conductive ring and the base. The connector maintains electrical coupling between the conductive ring and the base for movement of the conductive ring.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram of a plasma processing system with an example structure.

FIG. 2 is a diagram of an inductively coupled plasma processing apparatus with an example structure.

FIG. 3 is a diagram of a substrate support and a lifter in one exemplary embodiment.

FIG. 4 is a diagram of a substrate support and a lifter in another exemplary embodiment.

FIG. 5 is a diagram of a substrate processing system according to one exemplary embodiment.

FIG. 6 is a diagram of a substrate support and a lifter in still another exemplary embodiment.

FIG. 7 is a diagram of a substrate support and a lifter in still another exemplary embodiment.

FIG. 8 is a diagram of a substrate support and a lifter in still another exemplary embodiment.

FIG. 9 is a diagram of a substrate support and a lifter in still another exemplary embodiment.

FIG. 10 is a diagram of a capacitively coupled plasma processing apparatus with an example structure.

FIG. 11 is a diagram of a substrate support and a lifter in still another exemplary embodiment.

FIG. 12 is a diagram of a substrate support and a lifter in still another exemplary embodiment.

FIG. 13 is a diagram of a substrate support and a lifter in still another exemplary embodiment.

FIG. 14 is a flowchart of a plasma processing method according to one exemplary embodiment.

FIG. 15A is a diagram of an example imaging device used with the plasma processing apparatuses according to various exemplary embodiments, and FIG. 15B is a diagram of an example measurer used with the plasma processing apparatuses according to the various exemplary embodiments.

FIG. 16 is a flowchart of a plasma processing method according to another exemplary embodiment.

FIG. 17 is a flowchart of a plasma processing method according to still another exemplary embodiment.

FIG. 18 is a diagram of an example measurer used with the plasma processing apparatuses according to the various exemplary embodiments.

FIG. 19 is a diagram of an edge ring and a conductive ring in still another exemplary embodiment.

FIG. 20 is a diagram of an edge ring and a conductive ring in still another exemplary embodiment.

FIG. 21 is a diagram of a substrate support and a lifter in still another exemplary embodiment.

FIG. 22 is a graph showing experimental results.

FIG. 23 is a diagram of a substrate support and a lifter in one exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Exemplary embodiments will now be described in detail with reference to the drawings. In the drawings, like reference numerals denote like or corresponding components.

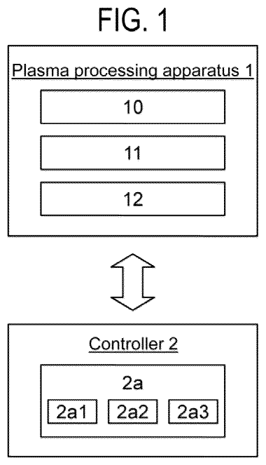

FIG. 1 is a diagram of a plasma processing system with an example structure. In one or more embodiments, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators including an alternating current (AC) plasma generator and a direct current (DC) plasma generator may be used. In one or more embodiments, an AC signal (AC power) used in the AC plasma generator has a frequency in a range of 100 kHz to 10 GHz. Thus, the AC signal includes a radio-frequency (RF) signal and a microwave signal. In one or more embodiments, the RF signal has a frequency in a range of 100 kHz to 150 MHz.

The controller 2 processes computer-executable instructions that cause the plasma processing apparatus 1 to perform various steps described in one or more embodiments of the disclosure. The controller 2 may control the components of the plasma processing apparatus 1 to perform the various steps described herein. In one or more embodiments, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2al. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

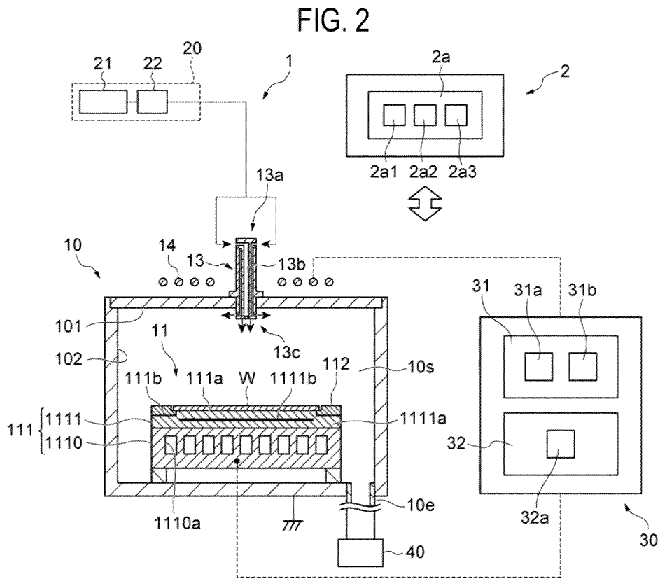

An example structure of an inductively coupled plasma processing apparatus as an example of the plasma processing apparatus 1 will now be described. FIG. 2 is a diagram of the inductively coupled plasma processing apparatus with an example structure.

The inductively coupled plasma processing apparatus 1 includes a plasma processing chamber 10, a gas supply 20, a power supply 30, and an exhaust system 40. The plasma processing chamber 10 includes a dielectric window 101. The plasma processing apparatus 1 also includes a substrate support 11, a gas guide unit, and an antenna 14. The substrate support 11 is located in the plasma processing chamber 10. The antenna 14 is located on or above the plasma processing chamber 10 (more specifically, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 is grounded.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is placed on the central area 111a of the body 111. The ring assembly 112 is placed on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one or more embodiments, the body 111 includes a base 1110 and an electrostatic chuck (ESC) 1111. The base 1110 includes a conductive member. The conductive member in the base 1110 may serve as a bias electrode. The ESC 1111 is located on the base 1110. The ESC 1111 includes a ceramic member 1111a and an electrostatic electrode 1111b inside the ceramic member 1111a. The ceramic member 1111a includes the central area 111a. In one or more embodiments, the ceramic member 1111a also includes the annular area 111b. Another member surrounding the ESC 1111, such as an annular ESC or an annular insulating member, may include the annular area 111b. In this case, the ring assembly 112 may be located on either the annular ESC or the annular insulating member, or may be located on both the ESC 1111 and the annular insulating member. At least one RF/DC electrode coupled to an RF power supply 31, a DC power supply 32, or both (described later) may be located inside the ceramic member 1111a. In this case, at least one RF/DC electrode serves as a bias electrode. The conductive member in the base 1110 and at least one RF/DC electrode may serve as multiple bias electrodes. The electrostatic electrode 1111b may also serve as a bias electrode. Thus, the substrate support 11 includes at least one bias electrode.

The ring assembly 112 includes one or more annular members. In one or more embodiments, one or more annular members include one or more edge rings and at least one cover ring. The edge ring is formed from a conductive material or an insulating material. The cover ring is formed from an insulating material.

The substrate support 11 may also include a temperature control module that adjusts the temperature of at least one of the ESC 1111, the ring assembly 112, or the substrate to be a target temperature. The temperature control module may include a heater, a heat transfer medium, a channel 1110a, or a combination of these. The channel 1110a allows a heat transfer fluid such as brine or gas to flow. In one or more embodiments, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central area 111a.

The gas guide unit introduces at least one process gas from the gas supply 20 into the plasma processing space 10s. In one or more embodiments, the gas guide unit includes a central gas injector (CGI) 13. The CGI 13 is located above the substrate support 11 and installed in a central opening in the dielectric window 101. The CGI 13 has at least one gas inlet 13a, at least one gas channel 13b, and at least one gas guide 13c. The process gas supplied to the gas inlet 13a passes through the gas channel 13b and is introduced into the plasma processing space 10s through the gas guide 13c. In addition to or in place of the CGI 13, the gas guide unit may include one or more side gas injectors (SGIs) installed in one or more openings in the sidewall 102.

The gas supply 20 may include at least one gas source 21 and at least one flow controller 22. In one or more embodiments, the gas supply 20 supplies at least one process gas from the corresponding gas source 21 to the gas guide unit through the corresponding flow controller 22. The flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes an RF power supply 31 that is coupled to the plasma processing chamber 10 through at least one impedance matching circuit. The RF power supply 31 provides at least one RF signal (RF power) to at least one bias electrode and the antenna 14. This causes plasma to be generated from at least one process gas supplied into the plasma processing space 10s. The RF power supply 31 may thus at least partially serve as the plasma generator 12. A bias RF signal is provided to at least one bias electrode to generate a bias potential in the substrate W, thus drawing ions in the plasma to the substrate W.

In one or more embodiments, the RF power supply 31 includes a first RF generator 31a and a second RF generator 31b. The first RF generator 31a is coupled to the antenna 14 through at least one impedance matching circuit to generate a source RF signal (source RF power) for generating plasma. In one or more embodiments, the source RF signal has a frequency in a range of 10 to 150 MHz. In one or more embodiments, the first RF generator 31a may generate multiple source RF signals with different frequencies. The generated one or more source RF signals are provided to the antenna 14.

The second RF generator 31b is coupled to at least one bias electrode through at least one impedance matching circuit and generates a bias RF signal (bias RF power). The bias RF signal may have a frequency that is the same as or different from the frequency of the source RF signal. In one or more embodiments, the bias RF signal has a lower frequency than the source RF signal. In one or more embodiments, the bias RF signal has a frequency in a range of 100 kHz to 60 MHz. In one or more embodiments, the second RF generator 31b may generate multiple bias RF signals with different frequencies. The generated one or more bias RF signals are provided to at least one bias electrode. In various embodiments, at least one of the source RF signal or the bias RF signal may be pulsed.

The power supply 30 may include the DC power supply 32 coupled to the plasma processing chamber 10. The DC power supply 32 includes a bias DC generator 32a. In one or more embodiments, the bias DC generator 32a is coupled to at least one bias electrode and generates a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a rectangular, trapezoidal, or triangular pulse waveform, or a combination of these pulse waveforms. In one or more embodiments, a waveform generator for generating a sequence of voltage pulses based on DC signals is coupled between the bias DC generator 32a and at least one bias electrode. Thus, the bias DC generator 32a and the waveform generator form a voltage pulse generator. The voltage pulses may have positive polarity or negative polarity. The sequence of voltage pulses may include one or more positive voltage pulses and one or more negative voltage pulses within one cycle. The power supply 30 may include the bias DC generator 32a in addition to the RF power supply 31, or the bias DC generator 32a may replace the second RF generator 31b.

The antenna 14 includes one or more coils. In one or more embodiments, the antenna 14 may include an outer coil and an inner coil that are coaxial with each other. In this case, the RF power supply 31 may be coupled to both the outer coil and the inner coil, or coupled to either the outer coil or the inner coil. When the RF power supply 31 is coupled to both the outer coil and the inner coil, a single RF generator may be connected to both the outer coil and the inner coil, or separate RF generators may be connected respectively to the outer coil and the inner coil.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

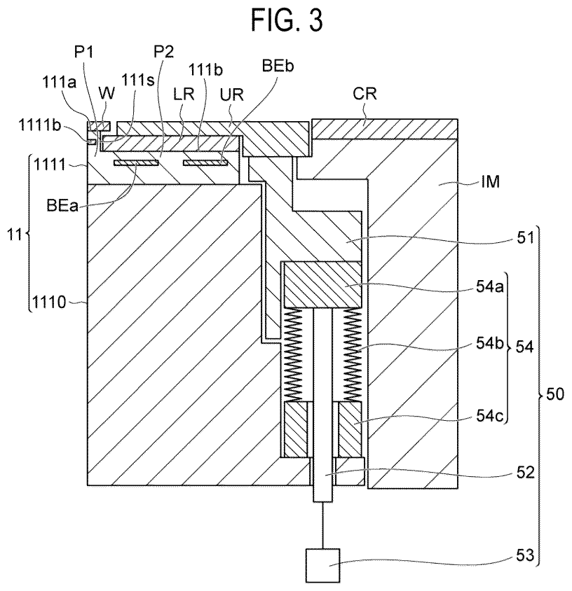

FIG. 3 will now be referred to. FIG. 3 is a diagram of a substrate support and a lifter in one exemplary embodiment. The substrate support 11 and a lifter 50 shown in FIG. 3 may be included in the plasma processing apparatus 1.

As described above, the substrate support 11 supports an edge ring UR (upper edge ring). The edge ring UR is a part of the ring assembly 112. The edge ring UR surrounds the substrate W on the substrate support 11. The edge ring UR is formed from a conductive material such as silicon, silicon carbide, or tungsten.

As described above, the substrate support 11 includes the base 1110 and the ESC 1111. The base 1110 is a conductive member or includes a conductive member inside. The base 1110 (or its conductive member) is electrically coupled to at least one bias power supply such as the second RF generator 31b, the bias DC generator 32a, or both. At least one bias power supply generates an electrical bias to draw ions from plasma into the substrate W on the substrate support 11. The electrical bias includes a sequence of the above bias RF signals, the above voltage pulses, or both.

The ESC 1111 is located on the base 1110. The ESC 1111 includes a first portion P1 and a second portion P2. The first portion P1 includes the substrate support surface (or the central area 111a) as its upper surface. Each of the first portion P1 and the substrate support surface is a substantially circular flat surface. The first portion P1 and the substrate support surface are coaxial with the substrate support 11. The first portion P1 includes the electrostatic electrode 1111b described above. When the electrostatic electrode 1111b receives a DC voltage applied from a DC power supply, an electrostatic attraction is generated between the first portion P1 and the substrate W. The first portion P1 holds the substrate W under the generated electrostatic attraction.

The second portion P2 extends circumferentially about the central axis of the substrate support 11 to surround the first portion P1. The second portion P2 includes the ring support surface (or the annular area 111b) as its upper surface. Each of the second portion P2 and the ring support surface is a substantially annular flat surface. The second portion P2 may include at least one electrostatic electrode. The second portion P2 may include an electrode BEa and an electrode BEb as at least one electrostatic electrode. The electrode BEa and the electrode BEb form a bipolar electrode. The electrode BEa and the electrode BEb receive a voltage applied from at least one power supply to have a potential difference between them. This generates an electrostatic attraction between the edge ring UR and the second portion P2. The second portion P2 holds the edge ring UR under the generated electrostatic attraction.

In one or more embodiments, the ring support surface extends at a lower level than the substrate support surface. In this case, the first portion P1 includes a sidewall surface 111s extending between the substrate support surface and the ring support surface. In this case, an edge ring LR (lower edge ring) may be located on the ring support surface along the sidewall surface 111s. The edge ring LR is a part of the ring assembly 112. The edge ring LR may be formed from a conductive material such as silicon, silicon carbide, or tungsten. In some embodiments, the edge ring LR may be formed from an insulating material such as quartz. In this case, the edge ring UR is located on the edge ring LR. The ring support surface and the sidewall surface 111s are protected by the edge ring LR.

As shown in FIG. 3, the substrate support 11 may further include a cover ring CR and an insulating member IM. The insulating member IM is formed from an insulating material such as quartz, and is substantially cylindrical. The insulating member IM extends circumferentially about the central axis of the substrate support 11 to surround the base 1110 and the ESC 1111. The cover ring CR is a substantially disk and is located on the insulating member IM to surround the edge ring UR.

The plasma processing apparatus 1 further includes the lifter 50. The lifter 50 includes a conductive ring 51, at least one rod 52, an actuator 53, and at least one connector 54.

The conductive ring 51 is formed from a metal such as aluminum or a conductive material, and is substantially a ring. The conductive ring 51 extends circumferentially about the central axis of the substrate support 11 to surround the base 1110 and the ESC 1111 inward from the insulating member IM. The conductive ring 51 is electrically coupled to the edge ring UR while supporting the edge ring UR placed on the conductive ring 51. More specifically, the conductive ring 51 is electrically conductive with or capacitively coupled to the edge ring UR while supporting the edge ring UR placed on the conductive ring 51. In the example in FIG. 3, the conductive ring 51 is conductive with the edge ring UR while supporting the edge ring UR placed on the conductive ring 51. The surface of the conductive ring 51 may have an exposed area covered with a film resistant to the plasma. The film may be formed from a material such as aluminum oxide or yttrium fluoride, and may be formed by anodic oxidation or thermal spraying.

The rod 52 extends in the vertical direction below the conductive ring 51. The rod 52 may be insulating. This structure can reduce the likelihood that the electrical bias flows into the actuator 53 through the rod 52. In one or more embodiments, the lifter 50 may include multiple rods 52 as at least one rod 52. The multiple rods 52 are arranged circumferentially about the central axis of the substrate support 11. The multiple rods 52 may be arranged circumferentially at equal intervals.

The actuator 53 is located below the rod 52 and is connected to the rod 52. The actuator 53 raises and lowers the edge ring with the rod 52 and the conductive ring 51. The actuator 53 may be, for example, a pneumatic cylinder, a hydraulic cylinder, or a motor.

The connector 54 electrically couples the conductive ring 51 and the base 1110 (or its conductive member). The connector 54 maintains the electrical coupling for the movement of the conductive ring 51. The connector 54 may be deformable in response to the movement of the conductive ring 51. The lifter 50 including multiple rods 52 may include multiple connectors 54 as at least one connector 54.

In the example shown in FIG. 3, the connector 54 includes an upper portion 54a, a deformable portion 54b, and a lower portion 54c. The upper portion 54a, the deformable portion 54b, and the lower portion 54c are each formed from a conductive material. The upper portion 54a is located immediately below the conductive ring 51 and is fixed to the conductive ring 51. The upper portion 54a is electrically conductive with the conductive ring 51. The lower portion 54c is located below the upper portion 54a and is fixed to the base 1110. The lower portion 54c is electrically conductive with the base 1110.

The deformable portion 54b extends between the upper portion 54a and the lower portion 54c. The deformable portion 54b has an upper end fixed to the upper portion 54a and a lower end fixed to the lower portion 54c. The deformable portion 54b is electrically conductive with the upper portion 54a and the lower portion 54c. The deformable portion 54b may be a bellows as shown in FIG. 3.

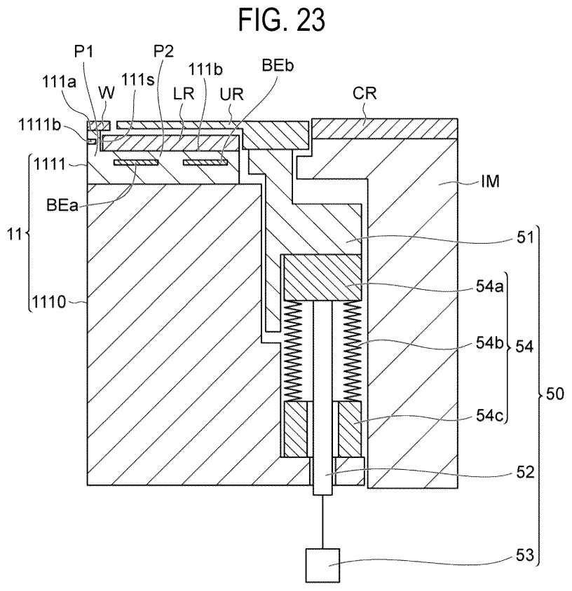

The rod 52 extends through the lower portion 54c, the deformable portion 54b, and to an area immediately below the upper portion 54a. When the rod 52 is moved upward by the actuator 53, the edge ring UR is raised upward with the upper portion 54a and the conductive ring 51 (refer to FIG. 23). The edge ring UR is raised by a decrease in its thickness to reduce the difference between the upper end position of a plasma sheath above the substrate W and the upper end position of a plasma sheath above the edge ring UR. In the plasma processing apparatus 1, the connector 54 maintains the electrical coupling between the base 1110 and the edge ring UR although the edge ring UR is raised upward from the ESC 1111. In the plasma processing apparatus 1, the edge ring UR does not enter an electrically floating state. Thus, the edge ring UR can reduce the difference between the upper end position of the plasma sheath above the substrate W and the upper end position of the plasma sheath above the edge ring UR.

The connector 54 may be a cylindrical member with multiple slits on the sidewall surface to be elastically deformable in its longitudinal direction. For example, the connector 54 may be a Flexus (flexible member).

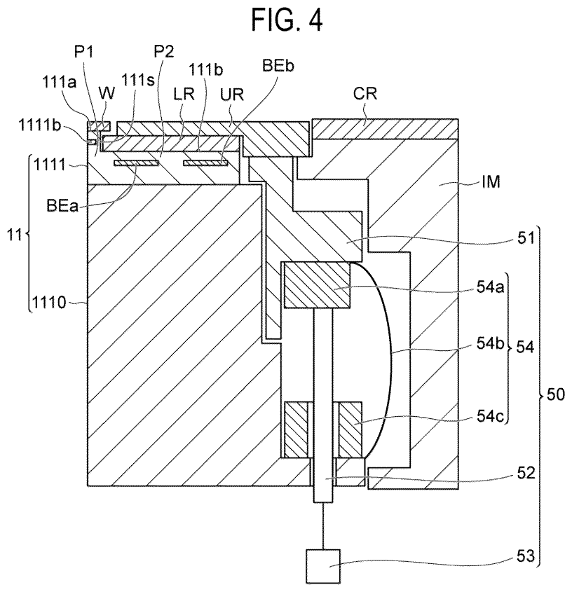

FIG. 4 will now be referred to. FIG. 4 is a diagram of a substrate support and a lifter in another exemplary embodiment. The substrate support 11 and the lifter 50 shown in FIG. 4 may be included in the plasma processing apparatus 1. The embodiment in FIG. 4 will now be described focusing on its differences from the embodiment in FIG. 3.

As shown in FIG. 4, the lifter 50 may include the deformable portion 54b that is a contact band in place of the bellows. The deformable portion 54b may have an upper end fixed to the conductive ring 51. The deformable portion 54b may have a lower end fixed to the base 1110. The deformable portion 54b shown in FIG. 4 is flexible in the vertical direction. As shown in FIG. 4, the deformable portion 54b may have a substantially arc shape protruding outward. In this case, the insulating member IM may have a recess to receive a part of the deformable portion 54b.

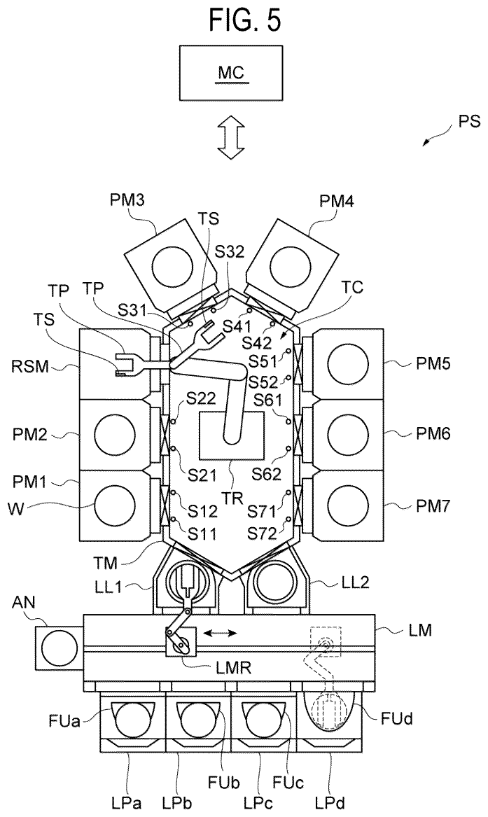

FIG. 5 will now be referred to. FIG. 5 is a diagram of a substrate processing system according to one exemplary embodiment. A substrate processing system PS shown in FIG. 5 includes a transfer module TM, multiple process modules PM1 to PM7 (multiple substrate processing modules), and a controller MC. The substrate processing system PS may further include tables LPa to LPd, containers FUa to FUd, a loader module LM, an aligner AN, a loadlock module LL1, a loadlock module LL2, and a stocker module RSM (ring stocker). The substrate processing system PS may include one or more tables, containers, and loadlock modules. The substrate processing system PS may include two or more process modules.

The tables LPa to LPd are arranged along one edge of the loader module LM. The containers FUa to FUd are mounted on the respective tables LPa to LPd. The containers FUa to FUd are each, for example, a container called a front-opening unified pod (FOUP). The containers FUa to FUd each store substrates W.

The loader module LM includes a transfer chamber. The transfer chamber in the loader module LM has an atmospheric pressure. The loader module LM includes a transfer robot LMR. The controller MC controls the transfer robot LMR. The transfer robot LMR transfers a substrate W through the transfer chamber in the loader module LM. The transfer robot LMR may transfer the substrate W between the containers FUa to FUd and the aligner AN, between the aligner AN and the loadlock modules LL1 and LL2, and between the loadlock modules LL1 and LL2 and the containers FUa to FUd. The aligner AN is connected to the loader module LM. The aligner AN adjusts (aligns) the position of the substrate W.

The loadlock module LL1 and the loadlock module LL2 are connected between the transfer chamber in the loader module LM and a transfer chamber TC in the transfer module TM. The loadlock module LL1 and the loadlock module LL2 each serve as a preliminary decompression chamber. A gate valve is located between the preliminary decompression chamber in each of the loadlock module LL1 and the loadlock module LL2 and the transfer chamber in the loader module LM. A gate valve is located between the preliminary decompression chamber in each of the loadlock module LL1 and the loadlock module LL2 and the transfer chamber TC in the transfer module TM.

The transfer module TM includes the transfer chamber TC (vacuum transfer chamber) and a transfer robot TR. The transfer chamber TC has an internal space that can be decompressed. The transfer robot TR includes picks TP (end-effectors). The transfer robot TR may include at least two picks TP. In the illustrated example, the transfer robot TR includes two picks TP. One pick TP is located above the other pick TP. The transfer robot TR transfers a substrate W on one of the two picks TP through the transfer chamber TC. The controller MC controls the transfer robot TR.

The transfer module TM may include position detection sensors S11 and S12. The position detection sensors S11 and S12 are installed on the transfer path for the substrate W and the edge ring from the transfer module TM to the process module PM1. The position detection sensors S11 and S12 are used to correct the positions of the substrate W and the edge ring that are transferred from the transfer module TM to the process module PM1. The position detection sensors S11 and S12 are located, for example, adjacent to the gate valve that separates the transfer module TM and the process module PM1. The position detection sensors S11 and S12 are located, for example, at a distance from each other being smaller than the outer diameter of the substrate W and smaller than the inner diameter of the edge ring. The transfer module TM may include position detection sensors S21, S22, S31, S32, S41, S42, S51, S52, S61, S62, S71, and S72, similarly to the position detection sensors S11 and S12. The position detection sensors S21 and S22 are installed on the transfer path for the substrate W and the edge ring from the transfer module TM to the process module PM2. The position detection sensors S31 and S32 are installed on the transfer path for the substrate W and the edge ring from the transfer module TM to the process module PM3. The position detection sensors S41 and S42 are installed on the transfer path for the substrate W and the edge ring from the transfer module TM to the process module PM4. The position detection sensors S51 and S52 are installed on the transfer path for the substrate W and the edge ring from the transfer module TM to the process module PM5. The position detection sensors S61 and S62 are installed on the transfer path for the substrate W and the edge ring from the transfer module TM to the process module PM6. The position detection sensors S71 and S72 are installed on the transfer path for the substrate W and the edge ring from the transfer module TM to the process module PM7.

In one or more embodiments, the transfer robot TR transfers an edge ring for a substrate support in one of the process modules PM1 to PM7. The edge ring corresponds to the edge ring UR or a set of rings including the edge ring UR and the edge ring LR. The edge ring is placed on either of the two picks TP and is transferred. Each pick TP includes a sensor TS. The sensor TS is an optical sensor that measures the position of a ring member, such as the edge ring, on the substrate support.

Each of the process modules PM1 to PM7 performs dedicated substrate processing and includes a processing chamber (substrate processing chamber). A gate valve is located between each processing chamber and the transfer chamber TC. At least one of the process modules PM1 to PM7 is the plasma processing apparatus 1.

The stocker module RSM (ring stocker) is connected to the transfer chamber TC with a gate valve. The stocker module RSM includes a chamber that can store multiple edge rings.

The controller MC controls the components of the substrate processing system PS. The controller MC may be a computer including a processor, a storage, an input device, and a display. The controller MC executes a control program stored in the storage to control the components of the substrate processing system PS based on recipe data stored in the storage.

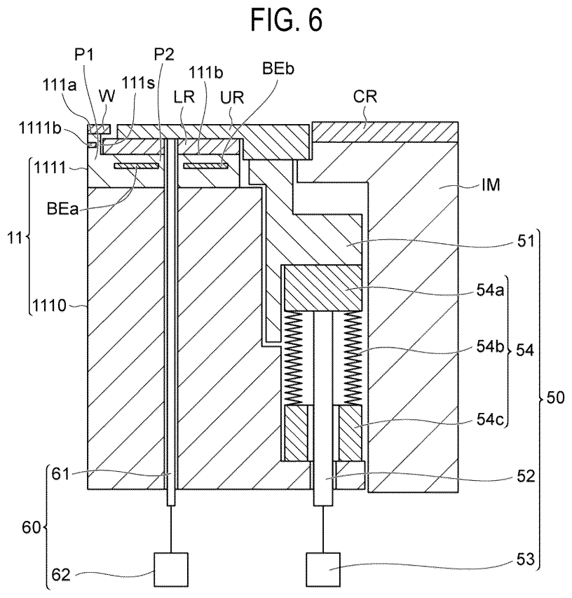

The plasma processing apparatus 1 used as the process module in the substrate processing system PS may include the substrate support 11 shown in any one of FIGS. 6 to 9. FIGS. 6 to 9 are each a diagram of a substrate support and a lifter in still another exemplary embodiment. In the embodiments in FIGS. 6 to 9, the edge ring in the plasma processing apparatus 1 is transferred by the transfer robot TR to be replaced with an edge ring in the stocker module RSM corresponding to the transferred edge ring.

In the embodiment in FIG. 6, the substrate support 11 has multiple through-holes extending through the substrate support 11 in the vertical direction. The through-holes in the substrate support 11 are arranged circumferentially about the central axis of the substrate support 11. The multiple through-holes in the substrate support 11 may be arranged at equal intervals. The edge ring LR has multiple through-holes aligned with the respective through-holes in the substrate support 11.

In the embodiment in FIG. 6, a lifter 60 can raise the edge ring UR upward from the substrate support 11. The lifter 60 includes multiple lift pins 61 and an actuator 62. The lift pins 61 are placed through the respective through-holes in the substrate support 11. The actuator 62 is connected to the lift pins 61 to move the lift pins 61 vertically.

With the upper ends of the lift pins 61 in contact with the edge ring UR, the actuator 62 moves the lift pins 61 upward to raise the edge ring UR upward from the substrate support 11. In this state, the transfer robot TR moves the corresponding pick TP to a position below the edge ring UR. The lift pins 61 are then moved downward to transfer the edge ring UR to the pick TP. The edge ring UR is then transferred into the stocker module RSM by the transfer robot TR.

An edge ring UR for replacement is then transferred from the stocker module RSM into the chamber 10 by the transfer robot TR. The lift pins 61 are moved upward by the actuator 62 to transfer the edge ring UR to the lift pins 61. The pick TP then moves out of the chamber 10, and the lift pins 61 are moved downward. This places the edge ring UR for replacement onto the substrate support 11.

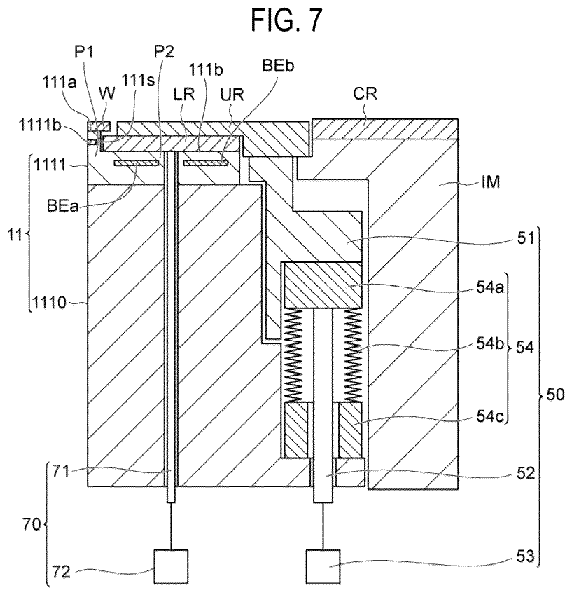

In the embodiment in FIG. 7, the substrate support 11 has multiple through-holes extending through the substrate support 11 in the vertical direction. The through-holes in the substrate support 11 are arranged circumferentially about the central axis of the substrate support 11. The through-holes in the substrate support 11 may be arranged circumferentially at equal intervals. The edge ring LR has no through-holes aligned with the respective through-holes in the substrate support 11.

In the embodiment in FIG. 7, a lifter 70 can raise the set of rings including the edge ring UR and the edge ring LR upward from the substrate support 11. The lifter 70 includes multiple lift pins 71 and an actuator 72. The lift pins 71 are placed through the respective through-holes in the substrate support 11. The actuator 72 is connected to the lift pins 71 to move the lift pins 71 vertically.

With the upper ends of the lift pins 71 in contact with the edge ring LR, the actuator 72 moves the lift pins 71 upward to raise the set of rings upward from the substrate support 11. In this state, the transfer robot TR moves the corresponding pick TP to a position below the set of rings. The lift pins 71 are then moved downward to transfer the set of rings to the pick TP. The set of rings is then transferred into the stocker module RSM by the transfer robot TR.

A set of rings for replacement is then transferred from the stocker module RSM into the chamber 10 by the transfer robot TR. The lift pins 71 are moved upward by the actuator 72 to transfer the set of rings to the lift pins 71. The pick TP then moves out of the chamber 10, and the lift pins 71 are moved downward. This places the set of rings for replacement onto the substrate support 11.

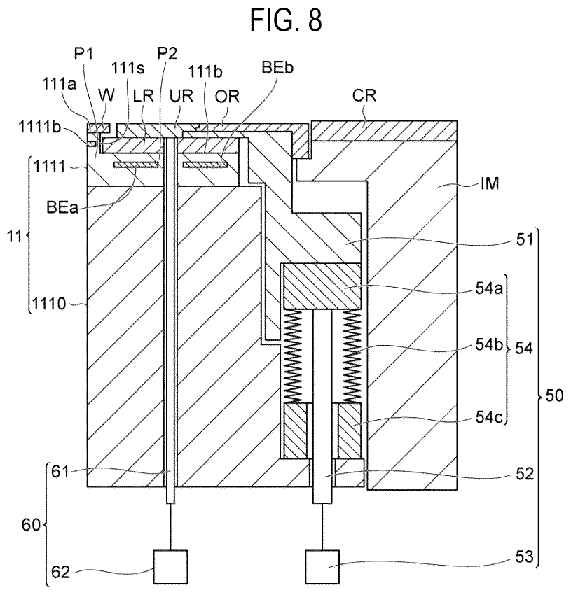

In the embodiment in FIG. 8, the conductive ring 51 extends onto an area of the edge ring LR to support, with its upper inner edge, the edge ring UR. In the embodiment in FIG. 8, an outer ring OR is located on the conductive ring 51 to surround the edge ring UR. The outer ring OR may be formed from an insulating material such as quartz. In the embodiment in FIG. 8 as well, the substrate support 11 has multiple through-holes extending through the substrate support 11, as in the embodiment in FIG. 6. The through-holes in the substrate support 11 are arranged circumferentially about the central axis of the substrate support 11. The through-holes in the substrate support 11 may be arranged circumferentially at equal intervals. The edge ring LR has multiple through-holes aligned with the respective through-holes in the substrate support 11.

In the embodiment in FIG. 8, the lifter 60 and the transfer robot TR operate to replace the edge ring UR in the same manner as the lifter 60 and the transfer robot TR operating to replace the edge ring UR in the embodiment in FIG. 6.

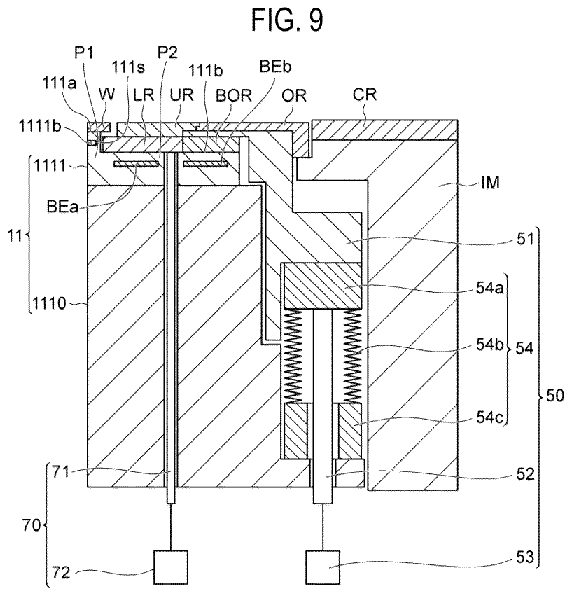

In the embodiment in FIG. 9, the edge ring LR has a smaller outer diameter than the edge ring UR. The edge ring UR is located on the edge ring LR, with the outer edge of the edge ring UR protruding radially outward from the edge ring LR. The conductive ring 51 has its upper inner edge supporting the outer edge of the edge ring UR. In the embodiment in FIG. 9, the outer ring OR is located on the conductive ring 51 to surround the edge ring UR. The outer ring OR may be formed from an insulating material such as quartz. In the embodiment in FIG. 9, another outer ring BOR is located below the upper end of the conductive ring 51 to surround the edge ring LR. The outer ring BOR may be formed from an insulating material such as quartz.

In the embodiment in FIG. 9 as well, the substrate support 11 has multiple through-holes extending through the substrate support 11, as in the embodiment in FIG. 7. The through-holes in the substrate support 11 are arranged circumferentially about the central axis of the substrate support 11. The through-holes in the substrate support 11 may be arranged circumferentially at equal intervals. The edge ring LR has no through-holes aligned with the respective through-holes in the substrate support 11.

In the embodiment in FIG. 9, the lifter 70 and the transfer robot TR operate to replace the edge ring in the same manner as the lifter 70 and the transfer robot TR operating to replace the edge ring in the embodiment in FIG. 7.

In still another exemplary embodiment, the plasma processing apparatus 1 may selectively replace the edge ring UR alone or the set of rings described above. For example, the plasma processing apparatus 1 may include both the lifter 60 and the lifter 70. In this case, the lift pins 61 and the lift pins 71 alternate circumferentially. The edge ring LR has no through-holes above the lift pins 71. This structure selectively allows replacement of the edge ring UR shown in FIG. 6 alone with the lifter 60 or replacement of the set of rings including the edge ring UR and the edge ring LR shown in FIG. 6 with the lifter 70. In some embodiments, this structure selectively allows replacement of the edge ring UR shown in FIG. 9 alone with the lifter 60 or replacement of the set of rings including the edge ring UR and the edge ring LR shown in FIG. 9 with the lifter 70.

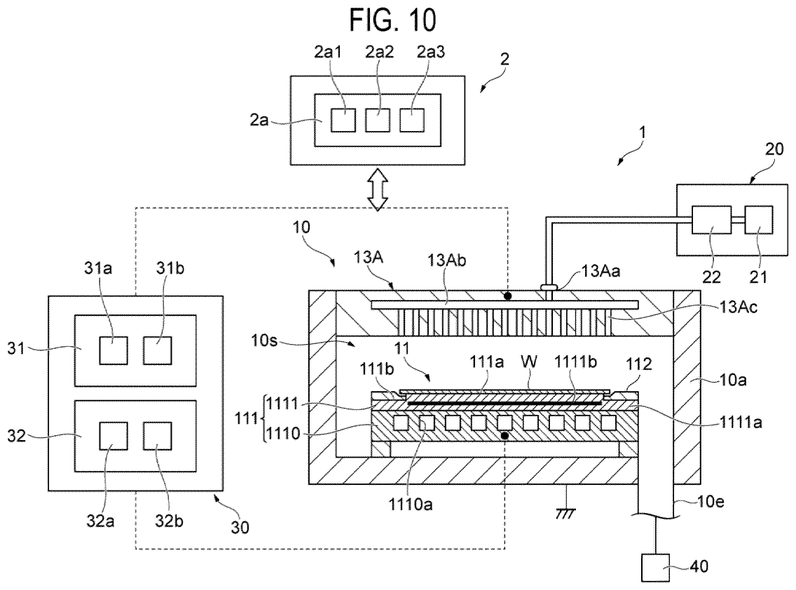

An example structure of a capacitively coupled plasma processing apparatus as another example of the plasma processing apparatus 1 will now be described. FIG. 10 is a diagram of the capacitively coupled plasma processing apparatus with the example structure. The plasma processing apparatus 1 shown in FIG. 10 includes the substrate support 11 and the lifter 50 in the plasma processing apparatus according to any one of the exemplary embodiments described above. The plasma processing apparatus 1 shown in FIG. 10 may include the lifter 60, the lifter 70, or both described above. The plasma processing apparatus 1 shown in FIG. 10 may be used as the process module in the substrate processing system PS. The capacitively coupled plasma processing apparatus 1 shown in FIG. 10 will now be described focusing on its differences from the inductively coupled plasma processing apparatus 1 shown in FIG. 2.

In the plasma processing apparatus 1 shown in FIG. 10, the gas guide unit includes a shower head 13A. The shower head 13A is located above the substrate support 11. In one or more embodiments, the shower head 13A defines at least a part of the ceiling of the plasma processing chamber 10. The plasma processing chamber 10 has a plasma processing space 10s defined by the shower head 13A, a sidewall 10a of the plasma processing chamber 10, and the substrate support 11. The plasma processing chamber 10 is grounded. The shower head 13A and the substrate support 11 are electrically insulated from the housing of the plasma processing chamber 10.

The shower head 13A introduces at least one process gas from the gas supply 20 into the plasma processing space 10s. The shower head 13A has at least one gas inlet 13Aa, at least one gas-diffusion compartment 13Ab, and multiple gas guides 13Ac. The process gas supplied to the gas inlet 13Aa passes through the gas-diffusion compartment 13Ab and is introduced into the plasma processing space 10s through the multiple gas guides 13Ac. The shower head 13A also includes at least one upper electrode. In addition to the shower head 13A, the gas guide unit may include one or more side gas injectors (SGIs) installed in one or more openings in the sidewall 10a.

In the plasma processing apparatus 1 shown in FIG. 10, the base 1110 (or its conductive member), or more specifically, a lower electrode is electrically coupled to an RF power supply, at least one bias power supply, or both. The RF power supply is the first RF generator 31a and is included in the plasma generator 12. At least one bias power supply includes the second RF generator 31b, the bias DC generator 32a (specifically, a first DC generator), or both. At least one bias power supply generates an electrical bias to draw ions from plasma into the substrate W on the substrate support 11. The electrical bias includes a sequence of the above bias RF signals, the above voltage pulses, or both.

In the plasma processing apparatus 1 shown in FIG. 10, the DC power supply 32 may further include a second DC generator 32b in addition to the bias DC generator 32a, or a first DC generator 32a. In one or more embodiments, the first DC generator 32a is coupled to at least one lower electrode and generates a first DC signal. The generated first DC signal is applied to at least one lower electrode. In one or more embodiments, the second DC generator 32b is coupled to at least one upper electrode and generates a second DC signal. The generated second DC signal is applied to at least one upper electrode.

In various embodiments, the second DC signal, in addition to the first DC signal, may be pulsed. In this case, a sequence of voltage pulses is applied to at least one lower electrode, at least one upper electrode, or both. The voltage pulses may have a rectangular, trapezoidal, triangular pulse waveform, or a combination of these pulse waveforms. In one or more embodiments, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31. The first DC generator 32a may replace the second RF generator 31b.

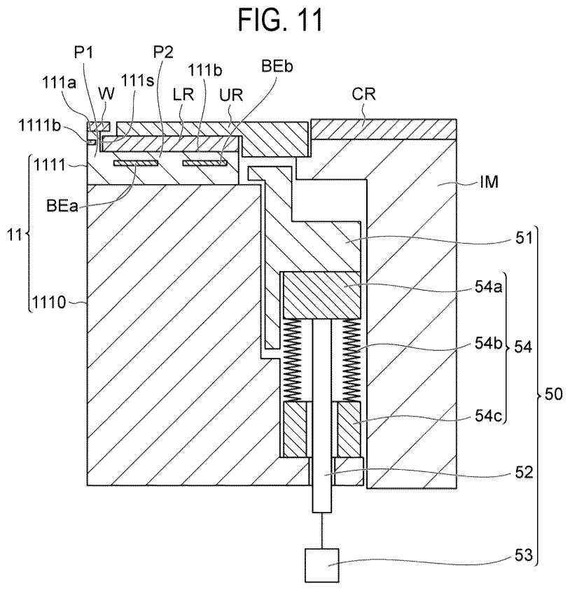

FIG. 11 will now be referred to. FIG. 11 is a diagram of a substrate support and a lifter in still another exemplary embodiment. The substrate support 11 and the lifter 50 shown in FIG. 11 may be included in the inductively coupled plasma processing apparatus 1 or the capacitively coupled plasma processing apparatus 1 described above. The substrate support 11 and the lifter 50 shown in FIG. 11 will now be described focusing on their differences from the substrate support 11 and the lifter 50 shown in FIG. 3.

The lifter 50 shown in FIG. 11 can electrically couple (e.g., allows electrical conduction between) the conductive ring 51 and the edge ring UR while supporting the edge ring UR on the conductive ring 51, similarly to the lifter 50 shown in FIG. 3. More specifically, the lifter 50 shown in FIG. 11 can establish a first state (e.g., a conductive state between the edge ring UR and the base 1110) in which the edge ring UR and the base 1110 are electrically coupled to each other. The lifter 50 shown in FIG. 11 can lower the conductive ring 51 downward with the rod 52 using the actuator 53 to separate the conductive ring 51 from the edge ring UR. In other words, the lifter 50 shown in FIG. 11 can disconnect the conductive ring 51 from the edge ring UR to establish a second state (e.g., a nonconductive state between the edge ring UR and the base 1110) in which the edge ring UR and the base 1110 are electrically disconnected from each other. The lifter 50 shown in FIG. 11 thus serves as a switch switchable between establishing the first state and establishing the second state.

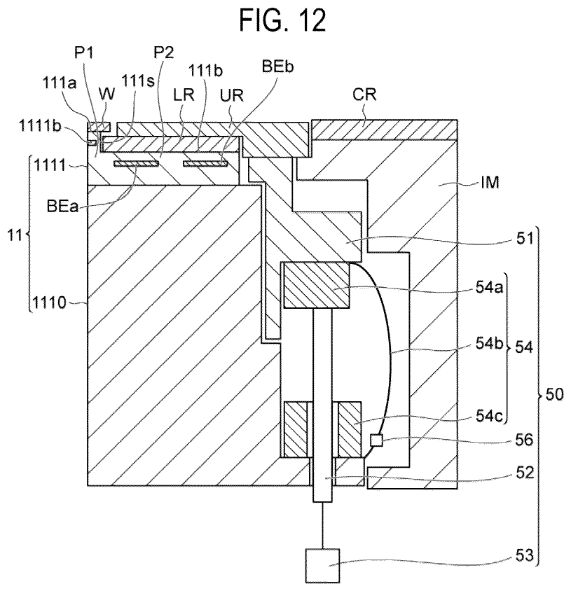

FIG. 12 will now be referred to. FIG. 12 is a diagram of a substrate support and a lifter in still another exemplary embodiment. The substrate support 11 and the lifter 50 shown in FIG. 12 may be included in the inductively coupled plasma processing apparatus 1 or the capacitively coupled plasma processing apparatus 1 described above. The substrate support 11 and the lifter 50 shown in FIG. 12 will now be described focusing on their differences from the substrate support 11 and the lifter 50 shown in FIG. 4.

The plasma processing apparatus 1 including the lifter 50 shown in FIG. 12 further includes a switch 56. The switch 56 may be a part of the lifter 50. The switch 56 includes a switching element and is connected between the connector 54 and the conductive ring 51 or between the connector 54 and the base 1110. The switching element in the switch 56 being ON (closed) establishes the first state in which the edge ring UR and the base 1110 are electrically coupled to each other (e.g., the conductive state between the edge ring UR and the base 1110). The switching element in the switch 56 being OFF (open) establishes the second state in which the edge ring UR and the base 1110 are electrically disconnected from each other (e.g., the nonconductive state between the edge ring UR and the base 1110).

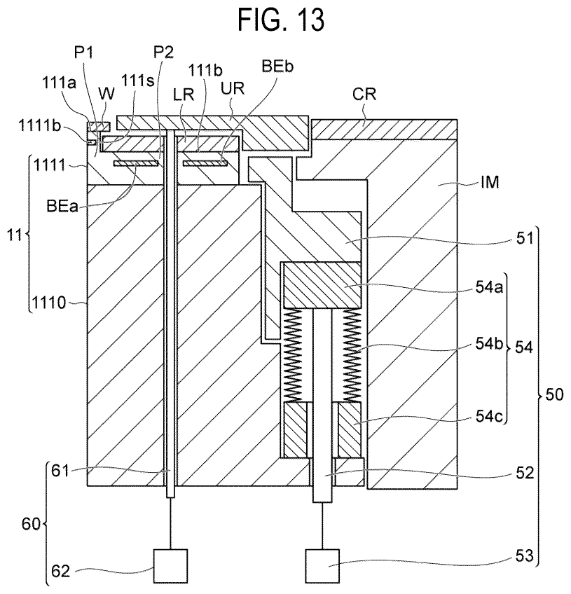

FIG. 13 will now be referred to. FIG. 13 is a diagram of a substrate support and a lifter in still another exemplary embodiment. The substrate support 11 and the lifter 50 shown in FIG. 13 may be included in the inductively coupled plasma processing apparatus 1 or the capacitively coupled plasma processing apparatus 1 described above. The substrate support 11 and the lifter 50 shown in FIG. 13 will now be described focusing on their differences from the substrate support 11 and the lifter 50 shown in FIG. 6.

The plasma processing apparatus 1 including the lifter 50 shown in FIG. 13 includes the lifter 60 as a switch switchable between establishing the first state and establishing the second state described above. All lift pins 61 in the lifter 60 are formed from an insulating material. When the lifter 60 positions all the lift pins 61 to have the edge ring UR supported on the conductive ring 51 and electrically coupled to the conductive ring 51, the first state (e.g., the conductive state between the edge ring UR and the base 1110) is established. When the lifter 60 raises the edge ring UR upward from the conductive ring 51 and separates the edge ring UR from the conductive ring 51, the second state (e.g., the nonconductive state between the edge ring UR and the base 1110) is established.

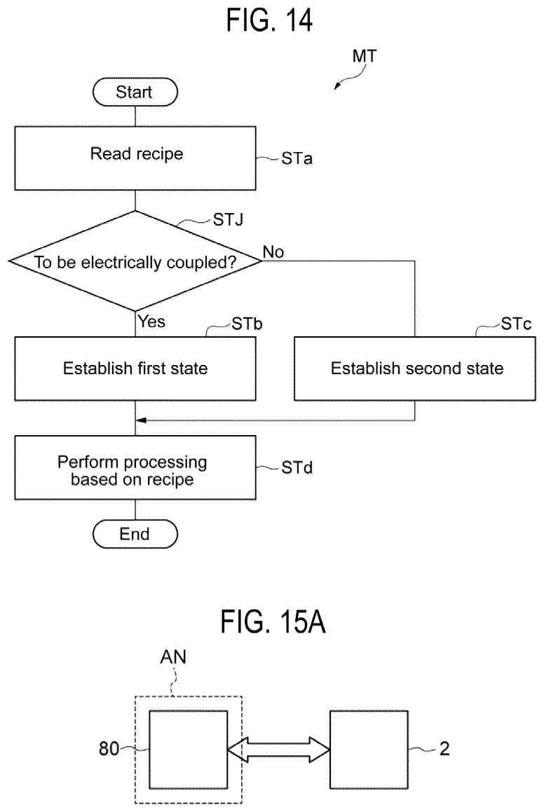

The switches described with reference to FIGS. 11 to 13 can each switch between establishing the first state and establishing the second state described above as appropriate. The controller 2 may control the corresponding switch. A plasma processing method performed with the plasma processing apparatus 1 including any of the switches shown in FIGS. 11 to 13 will now be described with reference to FIGS. 14 to 18.

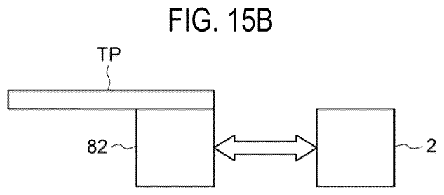

FIGS. 14 and 15A will now be referred to. FIG. 14 is a flowchart of a plasma processing method according to one exemplary embodiment. FIG. 15A is a diagram of an example imaging device used with the plasma processing apparatuses according to various exemplary embodiments. The plasma processing method shown in FIG. 14 (hereafter referred to as a method MT) may be performed using an imaging device 80 shown in FIG. 15A. The imaging device 80 may be located in the aligner AN. The imaging device 80 may be located at any position to capture an image of the substrate W.

The method MT is performed with the substrate W placed on the substrate support 11. The method MT starts from step STa. In step STa, the controller 2 reads a recipe.

In subsequent step STJ, the controller 2 determines whether the edge ring UR and the base 1110 are to be electrically coupled to each other (e.g., electrically conductive). In step STJ, the controller 2 may determine that the edge ring UR and the base 1110 are to be electrically coupled to each other when determining that the density of the plasma above the edge ring UR is to be increased. In contrast, the controller 2 may determine, in step STJ, that the edge ring UR and the base 1110 are not to be electrically coupled to each other when determining that the density of the plasma above the edge ring UR is not to be increased.

When determining that the density of the plasma above the edge ring UR is to be increased, the controller 2 controls, in step STb, the switch to establish the first state (e.g., the conductive state between the edge ring UR and the base 1110). When determining that the density of the plasma above the edge ring UR is not to be increased, the controller 2 controls, in step STc, the switch to establish the second state (e.g., the nonconductive state between the edge ring UR and the base 1110).

Step STd is then performed. In step STd, the controller 2 controls the components of the plasma processing apparatus 1 to perform plasma processing based on the recipe described above. When the edge ring UR and the base 1110 are electrically coupled to each other (e.g., electrically conductive) during step STd, the density of the plasma above the edge ring UR is increased in response to a source RF signal, an electrical bias, or both provided from the base 1110 to the edge ring UR through the conductive ring 51.

For the determination in step STJ, the controller 2 may obtain, from the imaging device 80, an image of the upper surface of a substrate W processed based on the same recipe before the substrate W is placed on the substrate support 11 in the plasma processing apparatus 1. The controller 2 may determine, based on the image, whether the density of the plasma above the edge ring UR is to be increased. In one or more embodiments, multiple holes may be formed in the substrate W in the plasma processing based on the recipe in step STd. In this case, when the controller 2 determines, based on the image obtained from the imaging device 80, that the roundness of the holes in an edge area of the substrate W and in the upper surface of the substrate W is less than or equal to a threshold in step STJ, the controller 2 performs step STb. When determining, based on the image obtained from the imaging device 80, that the roundness is greater than the threshold in step STJ, the controller 2 performs step STc. The roundness may be the ratio of the minimum width to the maximum width of the holes in the edge area of the substrate W and in the upper surface of the substrate W.

FIG. 15B will now be referred to with FIG. 14. FIG. 15B is a diagram of an example measurer used with the plasma processing apparatuses according to the various exemplary embodiments. With the method MT, a measurer 82 shown in FIG. 15B may be used. The measurer 82 is attached to a pick TP. The measurer 82 measures the thickness of a deposit on the edge ring UR. The measurer 82 may include an image sensor that captures an image of the edge ring UR, or may include another optical sensor that measures the thickness of the deposit on the edge ring UR.

The controller 2 may determine, based on the thickness of the deposit on the edge ring UR measured with the measurer 82, whether the density of the plasma above the edge ring UR is to be increased. In one or more embodiments, the plasma processing based on the recipe includes cleaning of the chamber 10 in step STd. In this case, when determining that the thickness of the deposit on the edge ring UR measured with the measurer 82 is greater than or equal to a threshold in step STJ, the controller 2 performs step STb. When determining that the thickness of the deposit on the edge ring UR measured with the measurer 82 is less than the threshold in step STJ, the controller 2 performs step STc. When step STd is performed after step STb, the density of the plasma above the edge ring UR is increased, thus facilitating removal of the deposit on the edge ring UR. During cleaning in step STd, a cleaning gas including an oxygen-containing gas such as O2 gas or other gases is used to perform cleaning with plasma generated from the cleaning gas. During cleaning in step STd, no object may be placed on the central area 111a of the substrate support 11, and a dummy wafer may be placed on the central portion 111a.

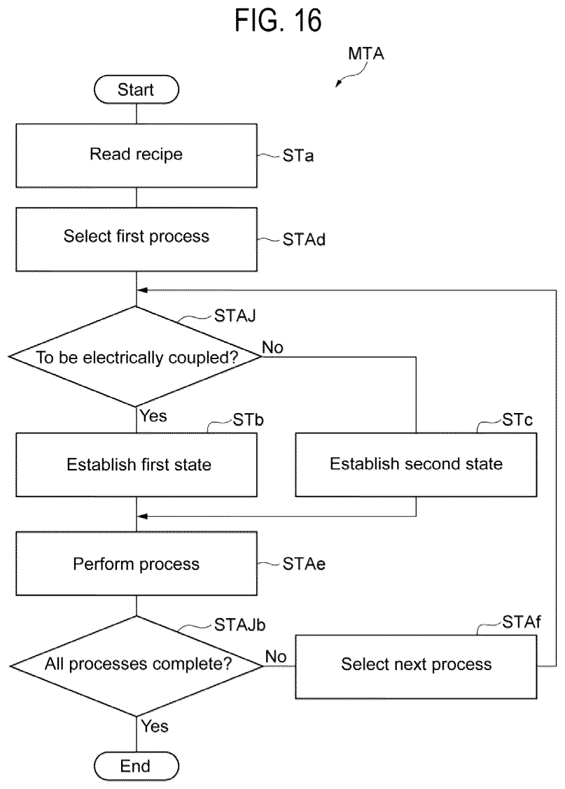

FIG. 16 will now be referred to. FIG. 16 is a flowchart of a plasma processing method according to another exemplary embodiment. The plasma processing method shown in FIG. 16 (hereafter referred to as a method MTA) starts from step STa, similarly to the method MT starting from step STa. The method MTA is performed with the substrate W placed on the substrate support 11.

In subsequent step STAd, the controller 2 selects the first process specified in the recipe. The recipe includes multiple processes, and specifies setting information about the electrical coupling (e.g., electrical conduction) between the edge ring UR and the base 1110 for each process. The setting information specifies the first state (e.g., the conductive state) or the second state (e.g., the nonconductive state) described above.

In subsequent step STAJ, the controller 2 determines, based on the setting information specified in the recipe for the selected process, whether the edge ring UR and the base 1110 are to be electrically coupled to each other. When determining that the edge ring UR and the base 1110 are to be electrically coupled to each other in step STAJ, the controller 2 performs step STb, as with the method MT. When determining that the edge ring UR and the base 1110 are not to be electrically coupled to each other in step STAJ, the controller 2 performs step STc, as with the method MT. The controller 2 then controls the components of the plasma processing apparatus 1 to perform a process selected in step STAc.

In subsequent step STAJb, the controller 2 determines whether all the processes included in the recipe are complete. When determining that all the processes are not complete, the controller 2 selects the next process included in the recipe in step STAf, and continues step STAJ and the subsequent steps. When determining that all the processes are complete in STAJb, the controller 2 ends the method MTA.

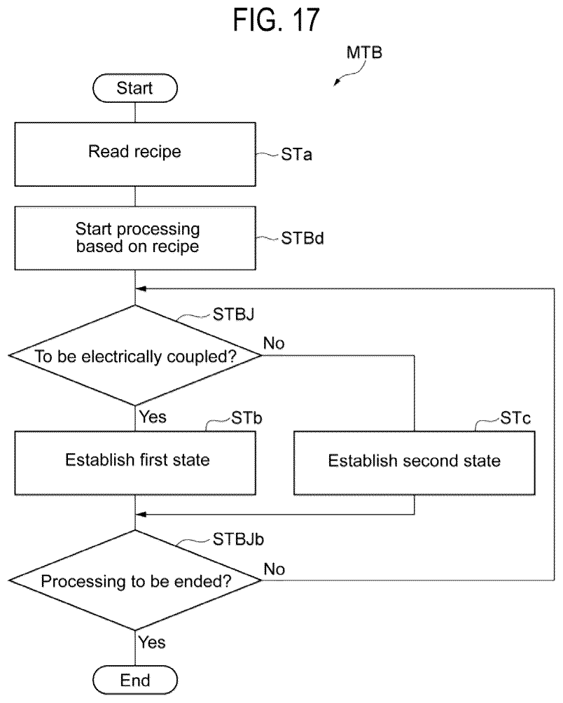

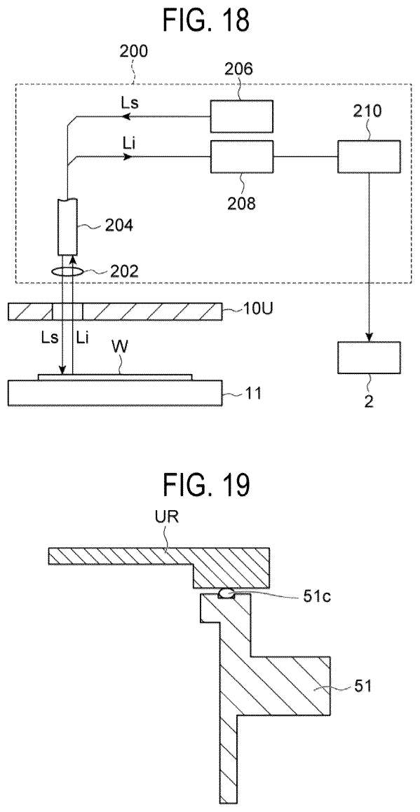

FIGS. 17 and 18 will now be referred to. FIG. 17 is a flowchart of a plasma processing method according to still another exemplary embodiment. FIG. 18 is a diagram of an example measurer used with the plasma processing apparatuses according to the various exemplary embodiments. The plasma processing method shown in FIG. 17 (hereafter referred to as a method MTB) may be performed using a measurer 200 shown in FIG. 18.

The measurer 200 includes a condenser lens 202, an optical fiber 204, a light source 206, a photodetector 208, and an arithmetic unit 210. The condenser lens 202 is located above a ceiling 10U of the chamber 10, and is optically connected to the substrate W on the substrate support 11 through an optical window in the ceiling 10U. The ceiling 10U corresponds to the dielectric window 101 or the shower head 13A.

The condenser lens 202 is optically connected to the light source 206 and the photodetector 208 (polychromator) through the optical fiber 204. The light source 206 emits light Ls. The light Ls emitted from the light source 206 is applied to the substrate W through the optical fiber 204 and the condenser lens 202. The light Ls is reflected from multiple positions at different heights in the substrate W to generate coherent light Li. The coherent light Li is input into the photodetector 208 through the condenser lens 202 and the optical fiber 204. The photodetector 208 detects the light intensity of the coherent light Li. The arithmetic unit 210 measures the depth of etching on the substrate W based on a change in the light intensity of the coherent light Li detected by the photodetector 208. The light intensity of the coherent light Li changes periodically in response to the depth of etching on the substrate W. This allows the arithmetic unit 210 to determine the depth of etching on the substrate W based on the change in the light intensity of the coherent light Li.

As shown in FIG. 17, the method MTB starts from step STa, similarly to the method MT starting from step STa. The method MTB is performed with the substrate W placed on the substrate support 11. In subsequent step STBd, the controller 2 starts the plasma processing based on the recipe, or more specifically, plasma etching on the substrate W. During plasma etching, the controller 2 controls the components of the plasma processing apparatus 1 based on the recipe. At the start of the plasma etching in step STBd, the second state (e.g., the nonconductive state between the edge ring UR and the base 1110) is established.

Steps STBJ to STBJb are performed while the plasma etching starting from step STBd is being performed. In step STBJ, the controller 2 determines whether the edge ring UR and the base 1110 are to be electrically coupled to each other (e.g., electrically conductive). More specifically, the controller 2 determines whether the depth of etching measured with the measurer 200 reaches a threshold. When determining that the depth of etching reaches the threshold, the controller 2 performs step STb. When determining that the depth of etching does not reach the threshold, the controller 2 performs step STc to maintain the second state (e.g., the nonconductive state).

In subsequent step STBJb, the controller 2 determines whether to end the processing starting from step STd, or more specifically, the plasma etching. When not ending the plasma etching, the controller 2 repeats step STBJ and the subsequent steps. When ending the plasma etching, the controller 2 ends the method MTB.

FIG. 19 will now be referred to. FIG. 19 is a diagram of an edge ring and a conductive ring in still another exemplary embodiment. As described above, the conductive ring 51 may come in contact with the edge ring UR to be electrically conductive with the edge ring UR and thus to establish the conductive state between the edge ring UR and the base 1110 as the first state in each of the exemplary embodiments. In some embodiments, as shown in FIG. 19, the conductive ring 51 may be electrically conductive with the edge ring UR through a member 51c to establish the conductive state between the edge ring UR and the base 1110 as the first state. The member 51c is formed from a conductive material such as a metal. The member 51c is held between the edge ring UR and the conductive ring 51 in the first state. The member 51c may be clastic. The member 51c may be a slant coil spring.

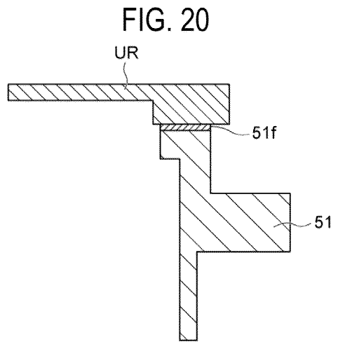

FIG. 20 will now be referred to. FIG. 20 is a diagram of an edge ring and a conductive ring in still another exemplary embodiment. The conductive ring 51 may be capacitively coupled to the edge ring UR to establish the first state. As shown in FIG. 20, the conductive ring 51 may have a dielectric area 51f on its upper surface. In this case, the conductive ring 51 is capacitively coupled to the edge ring UR while supporting the edge ring UR placed on the dielectric area 51f. The dielectric area 51f may be a film of a dielectric material. The dielectric area 51f may cover the surface of the conductive ring 51. The dielectric area 51f may be formed by thermal spraying of a material such as yttrium oxide.

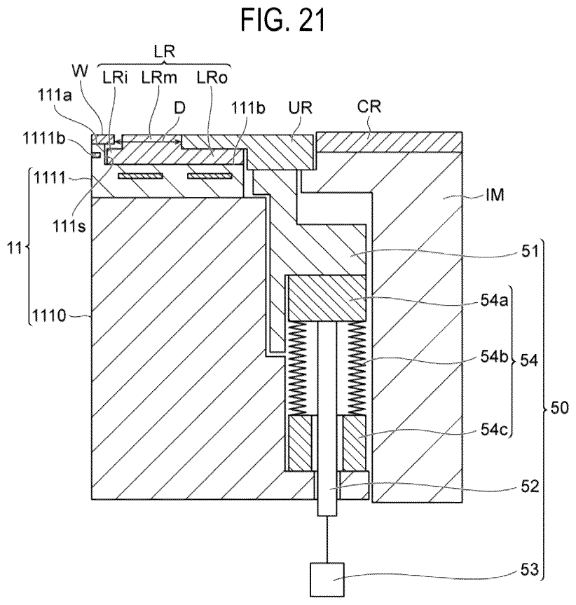

FIG. 21 will now be referred to. FIG. 21 is a diagram of a substrate support and a lifter in still another exemplary embodiment. In each of the exemplary embodiments described above, the edge ring UR and the edge ring LR may have the structure shown in FIG. 21. As shown in FIG. 21, the edge ring LR includes an inner circumferential portion LRi, an intermediate portion LRm, and an outer circumferential portion LRo. The inner circumferential portion LRi is annular and is placed on the ring support surface along the sidewall surface 111s. The edge area of the substrate W is located above the inner circumferential portion LRi. The outer circumferential portion LRo is annular and extends radially outward from the inner circumferential portion LRi. The edge ring UR is located on the outer circumferential portion LRo. The intermediate portion LRm is annular and extends between the inner circumferential portion LRi and the outer circumferential portion LRo. The intermediate portion LRm is located between the edge of the substrate W on the substrate support surface and the inner circumferential surface of the edge ring UR. The intermediate portion LRm has its upper surface positioned higher than the upper surface of the inner circumferential portion LRi and the upper surface of the outer circumferential portion LRo. The intermediate portion LRm may have a greater thickness than the inner circumferential portion LRi and the outer circumferential portion LRo.

When the edge ring UR is placed on the edge ring LR and in contact with the edge ring LR, the edge ring UR exchanges heat with the base 1110 through the edge ring LR and the ESC 1111. When the edge ring UR is raised upward from the edge ring LR, the temperature of the edge ring UR may increase. As shown in FIG. 21, the intermediate portion LRm radially separates the inner circumferential surface of the edge ring UR from the edge of the substrate W by a distance D. This structure reduces an increase in temperature of the edge area of the substrate W although the temperature of the edge ring UR increases. The edge ring UR shown in FIG. 21 also reduces the difference between the upper end position of the plasma sheath above the substrate W and the upper end position of the plasma sheath above the edge ring UR. This allows ions to be supplied perpendicularly to the edge area of the substrate W to form a vertical recess, such as a hole, in the edge area of the substrate W. The distance D may be less than or equal to 10 mm, less than or equal to 6 mm, or substantially 6 mm.

The results of experiments performed to evaluate the embodiments in FIGS. 3 and 21 will now be described. The experiments were conducted using the plasma processing apparatus 1 shown in FIG. 10 to perform plasma etching on a silicon-containing film on a sample substrate. The angles of holes formed in the silicon-containing film were obtained. For a hole extending in the thickness direction of the sample substrate, or more specifically, perpendicularly to the sample substrate, the hole has an angle of 90°. For a hole inclining outward from the sample substrate, the hole has an angle less than 90°. For a hole inclining toward the center of the sample substrate, the hole has an angle greater than 90°.

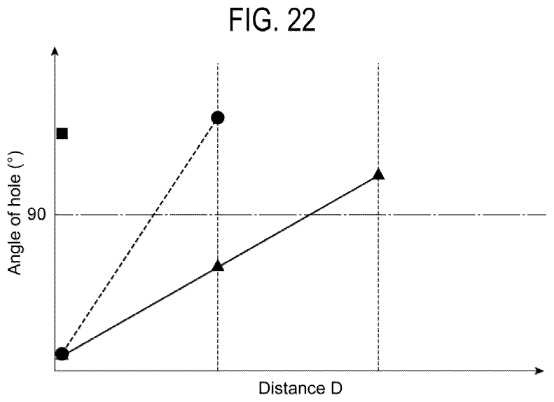

FIG. 22 is a graph showing the results of the experiments. In FIG. 22, the horizontal axis indicates the drive level of the conductive ring 51. For the edge ring UR placed on the edge ring LR and in contact with the edge ring LR, the drive level is zero. For the edge ring UR raised upward from the edge ring LR, the drive level is greater as the vertical distance between the edge ring UR and the edge ring LR increases. In FIG. 22, the vertical axis indicates the angle of a hole. The rectangular plot in FIG. 22 indicates the angle of a hole obtained when an unworn edge ring UR is used in the plasma processing apparatus 1 with the structure shown in FIG. 3, with the drive level being zero. The circular plot in FIG. 22 indicates the angle of a hole obtained when an edge ring UR having a thickness less than the unworn edge ring UR by 1 mm is used in the plasma processing apparatus 1 with the structure shown in FIG. 3. The triangular plot in FIG. 22 indicates the angle of a hole obtained when an edge ring UR having a thickness less than the unworn edge ring UR by 1 mm and having the distance D of 6 mm is used in the plasma processing apparatus 1 with the structure shown in FIG. 21. As shown in FIG. 22, the results reveal that the structure shown in FIG. 21 can adjust the angle of the hole based on the drive level, as with the structure shown in FIG. 3. The structure in FIG. 21 allows a smaller increase in the angle of the hole in response to an increase in the drive level than the structure in FIG. 3. This reveals that the structure in FIG. 21 can control the angle of the hole at a higher resolution.

Although the exemplary embodiments have been described above, the embodiments are not restrictive, and various additions, omissions, substitutions, and changes may be made. The components in the different embodiments may be combined to form another embodiment.

For example, any one of the containers FUa to FUd may be used as the stocker module RSM.

Various exemplary embodiments E1 to E19 included in the disclosure will now be described.

### [E1]

A plasma processing apparatus, comprising:
a chamber;
a substrate support in the chamber;
an edge ring to surround a substrate on the substrate support, the edge ring being conductive;
a lifter configured to raise and lower the edge ring;
a plasma generator including a radio-frequency power supply, the plasma generator being configured to generate plasma in the chamber; and
a bias power supply configured to generate an electrical bias to draw ions from the plasma into the substrate on the substrate support,
wherein the substrate support includes
a base electrically coupled to at least one of the bias power supply or the radio-frequency power supply, and
an electrostatic chuck on the base, and
wherein the lifter includes
a conductive ring configured to be electrically coupled to the edge ring while supporting the edge ring placed on the conductive ring,
a rod extending in a vertical direction below the conductive ring,
an actuator configured to raise and lower the edge ring with the rod and the conductive ring, and
a connector configured to electrically couple the conductive ring and the base, the connector being configured to maintain electrical coupling between the conductive ring and the base for movement of the conductive ring.

### [E2]

The plasma processing apparatus according to E1, wherein the connector is deformable in response to movement of the conductive ring.

### [E3]

The plasma processing apparatus according to E2, wherein the connector includes a bellows, a contact band, or a cylindrical member having a plurality of slits on a sidewall surface of the cylindrical member to be elastically deformable in a longitudinal direction of the cylindrical member.

### [E4]

The plasma processing apparatus according to any one of E1 to E3, wherein the rod is insulating.

### [E5]

The plasma processing apparatus according to any one of E1 to E4, wherein a surface of the conductive ring has an exposed area covered with a film resistant to the plasma.

### [E6]

The plasma processing apparatus according to any one of E1 to E5, wherein the edge ring is an upper edge ring,
wherein the plasma processing apparatus further comprises a lower edge ring on which the upper edge ring is located,
wherein the electrostatic chuck includes a first portion including a substrate support surface, and a second portion extending outside the first portion and having a ring support surface extending below the substrate support surface,
wherein the first portion includes a sidewall surface extending between the substrate support surface and the ring support surface, and the lower edge ring is located on the ring support surface along the sidewall surface.

### [E7]

The plasma processing apparatus according to E6, wherein the lower edge ring includes:
an inner circumferential portion along the sidewall surface,
an outer circumferential portion extending radially outward from the inner circumferential portion, the upper edge ring being located on the outer circumferential portion, and
an intermediate portion extending between the inner circumferential portion and the outer circumferential portion, the intermediate portion being located between an edge of the substrate on the substrate support surface and an inner circumferential surface of the upper edge ring.

### [E8]

The plasma processing apparatus according to E6 or E7, wherein the lower edge ring is conductive.

### [E9]

The plasma processing apparatus according to E6 or E7, wherein the lower edge ring is insulating.

### [E10]

The plasma processing apparatus according to any one of E6 to E9, further comprising another lifter configured to raise, from the electrostatic chuck, the upper edge ring or a set of rings including the upper edge ring and the lower edge ring.

### [E11]

The plasma processing apparatus according to any one of E1 to E10, further comprising: a switch configured to switch between establishing a first state in which the edge ring and the base are electrically coupled to each other and establishing a second state in which the edge ring and the base are electrically disconnected from each other.

### [E12]

The plasma processing apparatus according to E11, wherein the lifter is the switch configured to establish the second state by lowering the conductive ring with the actuator to separate the conductive ring from the edge ring.

### [E13]

The plasma processing apparatus according to E11, wherein the switch includes a switching element connected between the connector and the conductive ring or between the connector and the base.

### [E14]

The plasma processing apparatus according to E11, wherein the switch includes another lifter configured to establish the second state by raising the edge ring from the conductive ring.

### [E15]

The plasma processing apparatus according to E11, further comprising a controller configured to control the switch to establish the first state or the second state based on a read recipe.

### [E16]

The plasma processing apparatus according to E11, further comprising:
a measurer configured to measure a depth of etching on the substrate on the substrate support; and
a controller configured to control the switch to switch the second state to the first state in response to the depth of etching measured by the measurer reaching a threshold.

### [E17]

A substrate processing system comprising:
the plasma processing apparatus according to E10;
a transfer module including a transfer chamber and a transfer robot connected to the plasma processing apparatus;
a ring stocker configured to store the upper edge ring or the upper edge ring and the set of rings; and
a controller configured to control the other lifter and the transfer robot to replace the upper edge ring or the set of rings in the chamber in the plasma processing apparatus with the upper edge ring or the set of rings in the ring stocker through the transfer chamber.

### [E18]

A substrate processing system, comprising:
the plasma processing apparatus according to E11;
an imaging device configured to capture an image of a substrate etched by the plasma processing apparatus; and
a controller configured to control, in response to an image of a previously processed substrate having a roundness of a hole in an edge area of the substrate being less than or equal to a threshold, the switch to establish the first state to perform etching on a following substrate in the plasma processing apparatus.

### [E19]

A substrate processing system, comprising:
the plasma processing apparatus according to E11;
a measurer configured to measure a thickness of a deposit on the edge ring; and
a controller configured to control, during cleaning of the chamber, the switch to establish the second state in response to the thickness of the deposit being less than a threshold and to establish the first state in response to the thickness of the deposit being greater than or equal to the threshold.

The technique according to one exemplary embodiment reduces the difference between the upper end position of a plasma sheath above the edge ring and the upper end position of a plasma sheath above the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber;
a substrate support in the chamber;
an edge ring to surround a substrate on the substrate support, the edge ring being conductive;
a first lifter configured to raise and lower the edge ring;
a plasma generator including a radio-frequency power supply, the plasma generator being configured to generate plasma in the chamber; and
a bias power supply configured to generate an electrical bias to draw ions from the plasma into the substrate on the substrate support,
wherein the substrate support comprises:
a base electrically coupled to at least one of the bias power supply or the radio-frequency power supply; and
an electrostatic chuck on the base, and
wherein the first lifter comprises:
a conductive ring configured to be electrically coupled to the edge ring while supporting the edge ring that is disposed on the conductive ring;
a rod extending in a vertical direction below the conductive ring,
an actuator configured to raise and lower the edge ring with the rod and the conductive ring; and
a connector configured to electrically couple the conductive ring and the base, the connector being configured to maintain electrical coupling between the conductive ring and the base for movement of the conductive ring.

2. The plasma processing apparatus according to claim 1, wherein the connector is deformable in response to movement of the conductive ring.

3. The plasma processing apparatus according to claim 2, wherein the connector comprises a bellows, a contact band, or a cylindrical member having a plurality of slits on a sidewall surface of the cylindrical member to be elastically deformable in a longitudinal direction of the cylindrical member.

4. The plasma processing apparatus according to claim 1, wherein the rod is insulating.

5. The plasma processing apparatus according to claim 1, wherein a surface of the conductive ring has an exposed area covered with a film resistant to the plasma.

6. The plasma processing apparatus according to claim 1, wherein the edge ring is an upper edge ring,
wherein the plasma processing apparatus further comprises a lower edge ring on which the upper edge ring is located,
wherein the electrostatic chuck comprises:
a first portion including a substrate support surface; and
a second portion extending outside the first portion and having a ring support surface extending below the substrate support surface, and
wherein the first portion comprising:
a sidewall surface extending between the substrate support surface and the ring support surface, and
the lower edge ring is located on the ring support surface along the sidewall surface.

7. The plasma processing apparatus according to claim 6, wherein the lower edge ring comprises:
an inner circumferential portion along the sidewall surface;
an outer circumferential portion extending radially outward from the inner circumferential portion, the upper edge ring being located on the outer circumferential portion; and
an intermediate portion extending between the inner circumferential portion and the outer circumferential portion, the intermediate portion being located between an edge of the substrate on the substrate support surface and an inner circumferential surface of the upper edge ring.

8. The plasma processing apparatus according to claim 6, wherein the lower edge ring is conductive.

9. The plasma processing apparatus according to claim 6, wherein the lower edge ring is insulating.

10. The plasma processing apparatus according to claim 6, further comprising a second lifter configured to raise, from the electrostatic chuck, the upper edge ring or a set of rings including the upper edge ring and the lower edge ring.

11. The plasma processing apparatus according to claim 1, further comprising a switch configured to change between establishing a first state in which the edge ring and the base are electrically coupled to each other and a second state in which the edge ring and the base are electrically disconnected from each other.

12. The plasma processing apparatus according to claim 11, wherein the lifter is the switch and is configured to establish the second state by lowering the conductive ring with the actuator to separate the conductive ring from the edge ring.

13. The plasma processing apparatus according to claim 11, wherein the switch includes a switching element connected between the connector and the conductive ring or between the connector and the base.

14. The plasma processing apparatus according to claim 11, wherein the switch includes a second lifter configured to establish the second state by raising the edge ring from the conductive ring.

15. The plasma processing apparatus according to claim 11, further comprising a controller configured to control the switch to change to the first state or the second state based on a read recipe.

16. The plasma processing apparatus according to claim 11, further comprising:
a measurer configured to measure a depth of etching on the substrate on the substrate support; and
circuitry configured to control the switch to switch the second state to the first state in response to the depth of etching measured by the measurer reaching a threshold.

17. A substrate processing system, comprising:
the plasma processing apparatus according to claim 10;
a transfer module including a transfer chamber and a transfer robot connected to the plasma processing apparatus;
a ring stocker configured to store the upper edge ring or the upper edge ring and the set of rings; and
circuitry configured to control the second lifter and the transfer robot to replace the upper edge ring or the set of rings in the chamber in the plasma processing apparatus with the upper edge ring or the set of rings in the ring stocker through the transfer chamber.

18. A substrate processing system, comprising:
the plasma processing apparatus according to claim 11;
an imaging device configured to capture an image of a substrate etched by the plasma processing apparatus; and
circuitry configured to control, in response to an image of a previously processed substrate having a roundness of a hole in an edge area of the substrate being less than or equal to a threshold, the switch to establish the first state to perform etching on a following substrate in the plasma processing apparatus.

19. A substrate processing system, comprising:
the plasma processing apparatus according to claim 11;
a measurer configured to measure a thickness of a deposit on the edge ring; and
circuitry configured to control, during cleaning of the chamber, the switch to change to the second state in response to the thickness of the deposit being less than a threshold and to change to the first state in response to the thickness of the deposit being greater than or equal to the threshold.

20. A plasma processing apparatus, comprising:
a chamber;
a base disposed in the chamber;
an electrostatic chuck disposed on the base in the chamber;
a substrate support in the chamber;
an edge ring to surround a substrate on the substrate support, the edge ring being conductive;
a lifter configured to directly raise and lower the edge ring;
a plasma generator including a radio-frequency power supply, the plasma generator being configured to generate plasma in the chamber; and
a bias power supply configured to generate an electrical bias to draw ions from the plasma into the substrate on the substrate support,
wherein the substrate support comprises:
a base electrically coupled to at least one of the bias power supply or the radio-frequency power supply; and
an electrostatic chuck on the base, and
wherein the lifter comprises:
a conductive ring surrounding the edge ring and configured to be electrically coupled to the edge ring; and
a rod extending in a vertical direction below the conductive ring, and
a connector configured to electrically couple the conductive ring and the base, the connector being configured to maintain electrical coupling between the conductive ring and the base for movement of the conductive ring, the connector including:
an upper portion in contact with the conductive ring;
a lower portion disposed on the base; and
a deformable portion between the upper portion and the lower portion.
